(19) United States
(12) Patent Application Publication
(10) Pub. No.: US 2016/0088730 A1
(43) Pub. Date: Mar. 24, 2016

(54) PACKAGE SUBSTRATE AND MANUFACTURING METHOD THEREOF

(71) Applicant: AKM Electronics Technology (Suzhou) Co., Ltd., Suzhou City (CN)

(72) Inventor: Chengqiang CUI, Suzhou City (CN)

(21) Appl. No.: 14/891,131

(22) PCT Filed: Dec. 9, 2014
(86) PCT No.: PCT/CN2014/093408

§ 371 Date: Nov. 13, 2015

(30) Foreign Application Priority Data
Aug. 26, 2014 (CN) 201410425401.1

(51) Int. Cl. H05K 1/09; H05K 3/46; H05K 1/02

(52) U.S. Cl. CPC H05K 1/09; H05K 1/0298; H05K 3/46

(57) ABSTRACT

Provided is a package substrate and method for manufacturing package substrates. The method includes sticking a first photosensitive dry film on a first refractory laminate; eliminating the first photosensitive dry film except a predetermined area by exposure and development; sticking a layer of prepreg onto the first refractory laminate and the predetermined area of the first photosensitive dry film; sticking a second refractory laminate on the prepreg; and laser-cutting a slot. The predetermined area of first photosensitive dry film is sandwiched between the prepreg and the first refractory laminate, so there is no adhesion between the prepreg and the first refractory laminate, facilitating the slotting of the package substrate using the laser-cutting, and the removal of waste, enhancing the production efficiency.

### PRIORITY

This application is a National Phase Entry of PCT International Application No. PCT/CN2014/093408, which was filed on Dec. 9, 2014, and claims priority to Chinese Patent Application No. CN 201410425401.1, which was filed on Aug. 26, 2014, the contents of each of which are incorporated herein by reference.

### FIELD OF THE INVENTION

The present invention relates to the field of package substrates, in particular a novel package substrate and manufacturing method thereof.

### BACKGROUND OF THE INVENTION

Conventionally, electronic components are located on the surface of the printed circuit board, this structure is bound to increase the thickness of the board and such board cannot be used to manufacture multi-layers printed circuit boards. In order to meet the trend of electronics to be smaller, lighter and thinner, embedded-type multi-layers printed circuit boards, in which the electronic components were embedded, emerged.

The embedded-type multi-layers printed circuit board must be slotted. However, in the current slotting process, there is high viscidity of the glue between the prepreg and the laminate FR4, this process is operated in the manner of removing materials, i.e., waste), from the board by a milling cutter gradually in order to form slots, and this process requires much time and energy.

### SUMMARY OF THE INVENTION

An aspect relates to a manufacturing method of a package substrate, which facilitates removing the waste out fast.

Another aspect relates to a package substrate.

Provided is a manufacturing method of a package substrate, the method including: sticking a first photosensitive dry film on an upper surface of a first refractory laminate;

eliminating a first photosensitive dry film except a predetermined area for slotting, on the first refractory laminate, by exposure and development; sticking a layer of prepreg on the first refractory laminate and the predetermined area of the first photosensitive dry film; sticking a second refractory laminate on the layer of prepreg;laser-cutting a slot from the upper surface of the second refractory laminate to the upper surface of the first refractory laminate, along a contour of the predetermined area; and removing a waste while laser-cutting to form the slot.

Preferably, a second photosensitive dry film is stuck onto the upper surface of the second refractory laminate, and the second photosensitive dry film except a predetermined area for slotting, on the second refractory laminate is eliminated by exposure and development.

Preferably, an adhesive tape is stuck onto the second photosensitive dry film on the second refractory laminate, such that the waste cut from the first and second refractory laminates and the prepreg in the slot will be taken out by removing the adhesive tape.

After removing the waste, a layer of copper foil is provided on both the lower surface of the first refractory laminate and the upper surface of the second refractory laminate.

In the present invention, there is no glue between the first refractory laminate and the prepreg owing since the first photosensitive dry film is located there after exposure and development. As a result, the laser cutting can be introduced to enhance the speed of slotting and make the dislodging of waste convenient and efficient thus the production efficiency is promoted.

### BRIEF DESCRIPTION OF THE DRAWINGS

A preferable embodiment of the present invention will be described in detail hereinafter with reference to accompanying drawings, wherein

FIG. 1 shows step a of the slotting method of a package substrate according to the present invention;

FIG. 2 shows step b of the slotting method of a package substrate according to the present invention;

FIG. 3 shows step c of the slotting method of a package substrate according to the present invention;

FIG. 4 shows step d of the slotting method of a package substrate according to the present invention;

FIG. 5 shows steps e-f of the slotting method of a package substrate according to the present invention;

FIG. 6 shows step g of the slotting method of a package substrate according to the present invention; and

FIG. 7 is a top view of the package substrate according to the present invention.

### LIST OF REFERENCE CHARACTERS

11-refractory laminate
12-copper foil
2-prepreg
3-photosensitive dry film
4-slots

### DESCRIPTION OF THE PREFERRED EMBODIMENTS

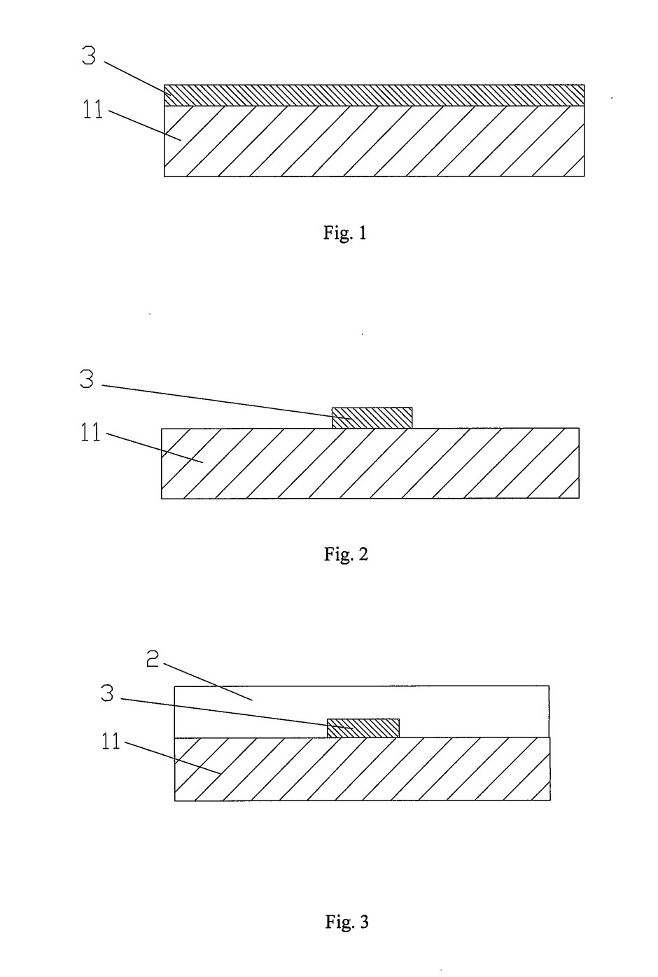

As shown in FIG. 1-6, a manufacturing method of a package substrate, comprises the steps of

a. sticking a first photosensitive dry film 3 on an upper surface of a first refractory laminate 11, as shown in FIG. 1;

b. eliminating a first photosensitive dry film 3 except the predetermined area for slotting, on the first refractory laminate 11, by exposure and development, as shown in FIG. 2;

c. sticking a layer of prepreg on the first refractory laminate 11 and the predetermined area of the first photosensitive dry film 3, as shown in FIG. 3;

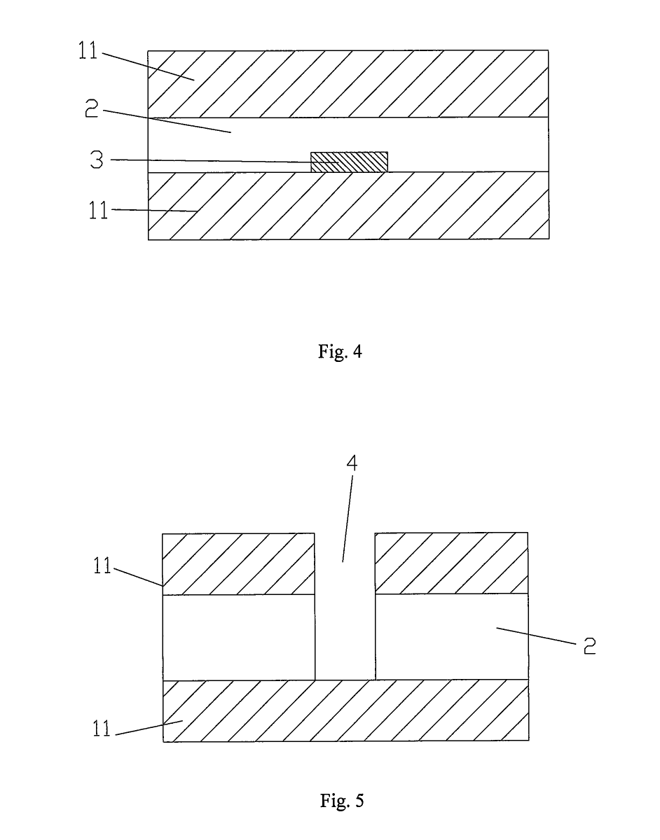

d. sticking a second refractory laminate 11 on the layer of prepreg, as shown in FIG. 4;

e. laser-cutting a slot 4 from the upper surface of the second refractory laminate 11 to the upper surface of the first refractory laminate 11, along a contour of the predetermined area; the predetermined area on the first refractory laminate 11 corresponds to that on the second refractory laminate, as shown in FIG. 5;

f. removing waste from in the slot 4, and forming the slot 4, as shown in FIG. 5; and

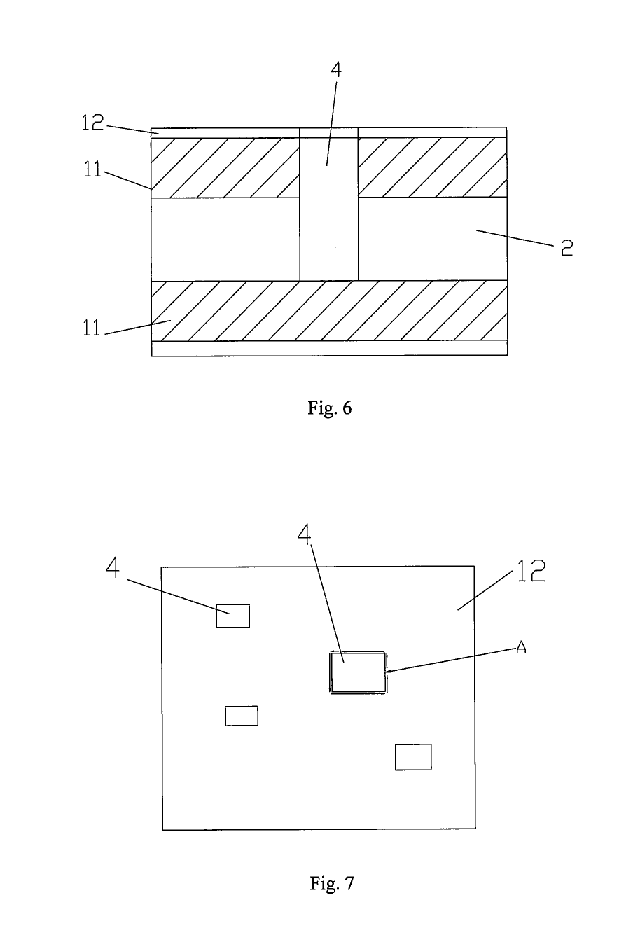

g. providing a layer of copper foil 12 on both the lower surface of the first refractory laminate 11 and the upper surface of the second refractory laminate 11, as shown in FIG. 6,

In order to ensure that the predetermined area on the first refractory laminate 11 can correspond to that on the second refractory laminate accurately in step e, a photosensitive dry film 3 can be employed on the second refractory laminate 11 to mark the predetermined area accurately in step d, as follows: sticking a second photosensitive dry film 3 on the upper surface of the second refractory laminate 11, and eliminating the second photosensitive dry film 11 except the predetermined area for slotting, on the second refractory laminate 11, by exposure and development.

In step f, the method of removing the waste from the slot 4 can be that, sticking an adhesive tape onto the predetermined area of the second photosensitive dry film 3 on the second refractory laminate 11, then removing the adhesive tape, such that the waste cut from the first and second refractory laminates 11 and the prepreg 2 in the slots 4 will be taken out.

A grade of the refractory laminates 11 is FR4.

As shown in FIG. 7, the “contour” hereinbefore means the edge line of the slot indicated by arrow A; the orientation of laser-cutting the slot is indicated by the arrows around the slot.

The package substrate shown in FIG. 7 can be manufactured by the method disclosed in the present invention. FIGS. 5 and 6 show the longitudinal cross-section of the package substrate manufactured by the method disclosed in the present invention, illustrating one of the slots 4 or a part of the package substrate.

The advantages of the manufacturing method of package substrates according to the present invention are as follows:

Using laser-cutting process, which makes no contact between cutting torch and work piece, no abrasion to the substrate, narrow kerf on the word piece, and merest deformation of the work piece, such quality and efficiency of cutting can ensure the integrality and performance of the whole package substrate.

Employing the adhesive tape onto the predetermined area of the second photosensitive dry film 3 on the second refractory laminate 11, facilitating removing the waste from the slots 4; when there are several slots 4, a piece of tape can adhere to the top of waste of all slots 4, such that all wastes can be taken out from all slots 4 by removing the adhesive tape.

Sticking the photosensitive dry film 3 on the predetermined area, such that the slot can be oriented accurately.

Providing a layer of copper foil 12 on external surfaces of both refractory laminates 11 in step g, such that the substrate can be protected.

A manufacturing method of package substrates according to the present invention, wherein the first photosensitive dry film 3 is located on the predetermined area after exposure and development, remaining on the first refractory laminate 11, and sandwiched between the prepreg 2 and the first refractory laminate 11, thereby there is neither contact nor adhesion between the prepreg 2 and the first refractory laminate 11, whereby the laser-cutting for the slot become easier, and the waste in the slot can be removed by pulling the adhesive tape out. The present invention facilitates the slotting of the package substrate and the dislodgement of waste enhances the efficiency.

The embodiment described hereinbefore is merely preferred embodiment of the present invention and not for purposes of any restrictions or limitations on the invention. It will be apparent that any non-substantive, obvious alterations or improvement by the technician of this technical field according to the present invention may be incorporated into ambit of claims of the present invention.

1. A manufacturing method of a package substrate, the method comprising:
a) sticking a first photosensitive dry film on an upper surface of a first refractory laminate;
b) eliminating a first photosensitive dry film except a predetermined area for slotting, on the first refractory laminate, by exposure and development;
c) sticking a layer of prepreg on the first refractory laminate and the predetermined area of the first photosensitive dry film;
d) sticking a second refractory laminate on the layer of prepreg;
e) laser-cutting a slot from an upper surface of the second refractory laminate to the upper surface of the first refractory laminate, along a contour of the predetermined area; and
f) removing a waste during cutting and forming the slot.

2. The manufacturing method of claim 1, wherein, in the step d), a second photosensitive dry film is stuck onto the upper surface of the second refractory laminate, and the second photosensitive dry film except a predetermined area for slotting, on the second refractory laminate is eliminated by means of the exposure and developing method.

3. The manufacturing method of claim 1, wherein, in the step f), an adhesive tape is stuck onto the second photosensitive dry film on the second refractory laminate, such that the waste cut from the first and second refractory laminates and the prepreg in the slot will be taken out by removing the adhesive tape.

4. The manufacturing method of claim 3, further comprising, after the step f):
providing a layer of copper foil on both the lower surface of the first refractory laminate and the upper surface of the second refractory laminate.

5. The manufacturing method of claim 1, wherein a grade of the refractory laminates is FR4.

6. A package substrate made by the manufacturing method of claim 1.
